(19) United States
(12) Patent Application Publication
(10) Pub. No.: US 2003/0064321 A1
(43) Pub. Date: Apr. 3, 2003

(54) Free-acid containing polymers and their use in photoresists

(75) Inventors: Sanjay Malik, Attleboro, MA (US); Ilya Rushkin, Walpole, MA (US); Gregory Spaziano, Providence, RI (US); David Brzozowy, Bristol, RI (US); Art Medina, Duluth, GA (US)

Correspondence Address: Paul D. Greeley, Esq., Ohlandt, Greeley, Ruggiero & Perle, L.L.P., 10th Floor, One Landmark Square, Stamford, CT, 06901-2682, US

(73) Assignee: ARCH SPECIALTY CHEMICALS, INC., NORWALK, CT

(21) Appl. No.: 10/229,771

(22) Filed: Aug. 28, 2002

Related U.S. Application Data
(60) Provisional application No. 60/316,330, filed on Aug. 31, 2001.

(51) Int. Cl. G03F 7/038; G03F 7/30

(52) U.S. Cl. 430/270.1; 430/325

(57) ABSTRACT

An improved binder resist for use in radiation sensitve photoresist compositions comprises a polymer having monomeric units of (a) carboxylic anhydride units, (b) alkenyl silane units and (c) units containing an acid labile group, and wherein the polymer contains from about 1 to about 3 mol % of free acid wherein the free acid is provided either by the presence in the polymer of a futher monomeric unit having free acids groups or by hydrolysis of sufficient of the carboxylic anhydride monomeric unit.

### RELATED APPLICATION

This application claims priority from U.S. Provisional Patent Application Serial No. 60/316,330 filed on Aug. 31, 2001.

### FIELD OF THE INVENTION

The present invention generally pertains to binder resins used in photolithography for the production of semiconductor devices and materials.

### BACKGROUND OF THE INVENTION

The continuing drive for miniaturization of semiconductor devices has caused an increased rigor in the photolithography used to delineate the fine patterns of those devices. The demands for finer resolution have caused the shrinkage of imaging wavelengths from 365 nm (high pressure mercury lamp) to 248 nm (KrF excimer lasers), to 193 nm (ArF excimer lasers) and beyond. As the patterns and wavelengths become finer, the materials properties of the photoresists used for pattern delineation have become more and more demanding. In particular, requirements of sensitivity, transparency, aesthetics of the image produced, and the selectivity of the resists to etch conditions for pattern transfer become more and more strenuous. Because of this, the traditional lithographic materials, such as novolaks, diazonaphthoquinones, etc., are unsuitable platforms for ultra large scale integration (ULSI) manufacture and beyond.

The principle of chemical amplification as a basis for photoresist operation has been known for some years (see U.S. Pat. No. 4,491,628). The most ubiquitous chemically amplified resists are those based on derivatized styrene polymers. Many variations of this theme have been proposed and commercialized. See J. Photopolymer. Sci. and Technology., 11(3), 1998, pp. 379-394, which provides an excellent summary of research efforts in Deep UV resist materials.

In 193-nm ArF excimer lithography, however, different materials are needed due to the high absorbance of the core styrene moieties. Acrylate platforms were proposed as vehicles for surmounting the transparency problem, but these systems were deficient in etch resistance (see J. Vac. Sci. Technology., B9, 3357 (1991), or J. Photopolymer. Sci. and Technology., 8, No. 4,(1995) p. 623 or U.S. Pat. No. 5,580,694 for example). The etch resistance of these materials could be augmented by incorporation of pendant alicyclic moieties (see J. Photopolymer. Sci. and Technology., 9, No. 3,(1996) p. 387; or J. Photopolymer. Sci. and Technology., 9, No. 3,(1996) p. 475; or Japanese Patent Application No. A973173 for possible alicyclics used), but the high hydrophobicity this imparted on the resins caused other processing problems, including de-wetting during development or adhesion loss or micropeeling.

Another approach to solving the need for high etch resistance involves the use of multilayer resist systems. In this approach, a thin, silicon-containing imaging layer is deposited over a thicker planarizing layer and exposed imagewise. The exposed areas of the imaging layer are then developed, and both layers are exposed to an oxidative etch. The planarizing layer is removed in the exposed areas, but in the unexposed areas, the imaging layer is oxidized to a layer of silicon dioxide, which impedes the etching and provides a basis for selectivity.

Examples of bilayer imaging systems have been disclosed in commonly assigned U.S. Pat. No. 6,146,793, U.S. Pat. No. 6,165,682, and U.S. patent application Ser. No. 09/576,146. U.S. Pat. No. 6,165,682 discloses resists containing polymers with and without an optional monomer containing a carboxylic acid moiety. We have recently found that such compositions give good lithographic performance in applications using a “bright field” mask (e.g., masks where the chrome pattern covers only a small portion of the mask substrate) but give inferior performance in “dark field” mask applications (e.g., masks where the chrome pattern covers most of the mask substrate such as for contact holes). The features tend to have an undesired cusp at the top of the feature leading to poor metrology and poor pattern transfer into the underlying substrate. U.S. Pat. No. 6,165,682 also discloses bilayer photoresist polymers containing an optional carboxylic acid. U.S. patent application Ser. No. 09/576,146 discloses bilayer photoresist polymers also containing a carboxylic acid moiety. Such polymers containing carboxylic acid moieties tend to suffer from lower contrast, poor profiles, and undesired unexposed film thickness loss. Neither of these two applications teach advantages of any specific concentration or optimum range of concentration of carboxylic acid moieties on performance.

### SUMMARY OF THE INVENTION

In the present invention it has been unexpectedly discovered that modifying the dissolution behavior of the polymer used as binder resin decreases the cusping of the features. This has been accomplished this by incorporating small amounts of free acid into the polymer, thereby increasing its intrinsic solubility which results in the elimination of the cusping behavior while desirable resist properties, such as contrast and depth of focus, are maintained. The present invention relates to modulation of the dissolution characteristics of a photoresist to avoid cusp formation. In the present invention, dissolution behavior is modulated by incorporation of free carboxylic acid into at least a portion of the binder resin or resins in a concentration range of between about 0.1% to about 3 mol %, preferably from about 1.5 to about 2.5 mol %, by weight of total binder resin.

### DETAILED DESCRIPTION AND PREFERRED EMBODIMENTS OF INVENTION

The invention is achieved through use of a binder resin system which comprises a polymer. The polymer comprises: (1) a first monomer M1 which is a polymerizable carboxylic acid anhydride such as maleic anhydride or itaconic anhydride; (2) a second monomer M2 which is an alkenyl silane, such as allyl trimethylsilane, vinyl trimethyl silane, or other silane; (3) a third monomer M3 which is a monomer with an acid labile group, such monomer yielding a base-soluble group on reaction with acid, as for example, t-butyl acrylate, t-butyl methacrylate, t-amyl acrylate or methacrylate, tetrahydropyranyl acrylate or methacrylate, or other acid-sensitive monomer as described in U.S. Pat. No. 6,136,501, which is incorporated herein by reference; and (4) a fourth monomer M4 which is a monomer with a free acid group. This acid could come from incorporation of a discrete, specific monomer, such as acrylic or methacrylic acid or vinyl acetic acid, or maleic acid or substituted maleic acid. It could also come from modification of a pre-formed polymer. For example, if a polymer contains carboxylic acid anhydride and no free carboxylic acid, it can be converted into a polymer of the present invention by inducing hydrolysis of a portion of the anhydride by treatment of the polymer with small amounts of water or alcohol to yield a polymer with free carboxylic acid. The polymer may also optionally contain a fifth monomer M5 which is any other monomer with a polymerizable C═C bond which modifies the properties of the final resin, such as alkyl acrylates, vinyl acetates, styrene, hydroxystyrene, and the like.

The compositional ranges for each of the monomers is about 15-50 mol % of M1; 15-50 mol % of M2, with the proviso that the total silicon content of the polymer is 4% to 15% by weight; 10-40 mol % of M3; 0.1-3 mol % of M4; and the remainder, if any, being provided by monomer or monomers of the type M5. The polymers thus described may be used alone or combined with other polymers in a range of between about 0.1% to about 100% by weight of the total polymer product.

The present invention further relates to radiation sensitive photoresist compositions comprising these polymers, a photoacid generator compound and a solvent capable of dissolving the polymer and photoacid generator compound. Many other additives, including additional photoacid generators, photobase generators, basic compounds for limiting diffusion lengths of photogenerated acids, crosslinking agents, dissolution inhibitors, adhesion promoters, surfactants, and the like may be included in useful photoresists according to the present invention.

Any suitable photoacid generator compound may be employed in the radiation sensitive photoresist compositions. Examples of suitable photoacid generators include, but are not limited to, iodonium, sulfonium, or other onium salts, which decompose in the presence of light to yield acids; oxime sulfonates; nitrobenzyl esters of carboxylic or sulfonic acids; alkyl halides or gem-dihalides which release halo acids.

Preferred photoacid generators are those generating sulfonic acids. Suitable classes of photoacid generators generating sulfonic acids include, but are not limited to, sulfonium or iodonium salts, oximidosulfonates, bissulfonyldiazomethane compounds, and nitrobenzylsulfonate esters. Suitable photoacid generator compounds are disclosed, for example, in U.S. Pat. Nos. 5,558,978 and 5,468,589 which are incorporated herein by reference. Particularly preferred are diaryl or dialkyl iodonium salts of strong acids or triaryl, diarylalkyl, dialkylaryl, or trialkyl substituted sulfonium salts of sulfonic acids.

Suitable examples of photoacid generators are triphenylsulfonium bromide, triphenylsulfonium chloride, triphenylsulfonium iodide, triphenylsulfonium hexafluorophosphate, triphenylsulfonium hexafluoroarsenate, triphenylsulfonium hexafluoroarsenate, triphenylsulfonium trifluoromethanesulfonate, diphenylethylsulfonium chloride, phenacyldimethylsulfonium chloride, phenacyltetrahydrothiophenium chloride, 4-nitrophenacyltetrahydrothiopheniumn chloride, and 4-hydroxy-2-methylphenylhexahydrothiopyrylium chloride.

Additional examples of suitable photoacid generators for use in this invention include triphenylsulfonium perfluorooctanesulfonate, triphenylsulfonium perfluorobutanesulfonate, methylphenyldiphenylsulfonium perfluorooctanesulfonate, methylphenyldiphenysulfonium perfluorooctanesulfonate, 4-n-butoxyphenyldiphenylsulfonium perfluorobutanesulfonate, 2,4,6-trimethylphenyldiphenylsulfonium perfluorobutanesulfonate, 2,4,6-trimethylphenyldiphenylsulfonium benzenesulfonate, 2,4,6-trimethylphenyldiphenylsulfonium 2,4,6-triisopropylbenzenesulfonate, phenylthiophenyldiphenylsulfonium 4-dodecylbenzensulfonic acid, tris(-t-butylphenyl)sulfonium perfluorooctanesulfonate, tris(-t-butylphenyl)sulfonium perfluorobutanesulfonate, tris(-t-butylphenyl)sulfonium 2,4,6-triisopropylbenzenesulfonate, tris(-t-butylphenyl)sulfonium benzenesulfonate, and phenylthiophenyldiphenylsulfonium perfluorooctanesulfonate.

Examples of suitable iodonium salts for use in this invention include, but are not limited to, diphenyl iodonium perfluorobutanesulfonate, bis-(t-butylphenyl)iodonium perfluorobutanesulfonate, bis-(t-butylphenyl)iodonium perfluorooctanesulfonate, diphenyl iodonium perfluorooctanesulfonate, bis-(t-butylphenyl)iodonium benzenesulfonate, bis-(t-butylphenyl)iodonium 2,4,6-triisopropylbenzenesulfonate, and diphenyliodonium 4-methoxybenzensulfonate.

Further examples of suitable photoacid generators for use in this invention are bis(p-toluenesulfonyl)diazomethane, methylsulfonyl p-toluenesulfonyldiazomethane, 1-cyclo-hexylsulfonyl-1-(1,1-dimethylethylsulfonyl)diazometane, bis(1,1-dimethylethylsulfonyl)diazomethane, bis(1-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfony1)propiophenone, 2-methanesulfonyl-2-methyl-(4-methylthiopropiophenone, 2,4-methy1-2-(p-toluenesulfonyl)pent-3-one, 1-diazo-1-methylsulfonyl-4-phenyl-2-butanone, 2-(cyclohexylcarbonyl-2-(p-toluenesulfonyl)propane, 1-cyclohexylsulfonyl-1cyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-butanone, 1-acetyl-1-(1-methylethylsulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, and 2,4-dinitrobenzyl p-trifluoromethylbenzenesulfonate.

The photoacid generator compound is typically employed in the amounts of about 0.0001 to 20% by weight of polymer solids and more preferably about 1% to 10% by weight of polymer solids. Preferred photoacid generators are sulfonium salts. The photoacid generator may be used alone or in combination with one or more photoacid generators. The percentage of each photoacid generator in photoacid generator mixtures is between about 10% to about 90% of the total photoacid generator mixture. Preferred photoacid generator mixtures contain about 2 or 3 photoacid generators. Such mixtures may be of the same class or different classes. Examples of preferred mixtures include sulfonium salts with bissulfonyldiazomethane compounds, sulfonium salts and imidosulfonates, and two sulfonium salts.

The choice of solvent for the photoresist composition and the concentration thereof depends principally on the type of functionalities incorporated in the acid labile polymer, the photoacid generator, and the coating method. The solvent should be inert, should dissolve all the components in the photoresist, should not undergo any chemical reaction with the components and should be re-removable on drying after coating. Suitable solvents for the photoresist composition may include ketones, ethers and esters, such as methyl ethyl ketone, methyl isobutyl ketone, 2-heptanone, cyclopentanone, cyclohexanone, 2-methoxy-1-propylene acetate, 2-ethoxyethyl acetate, I-methoxy-2-propyl acetate, 1,2-dimethoxy ethane ethyl acetate, cellosolve acetate, propylene glycol monoethyl ether acetate, methyl pyruvate, ethyl pyruvate, methyl 3-methoxypropionate, ethyl 3-methoxypropionate, N-methyl-2-pyrrolidone, 1,4-dioxane, diethylene glycol dimethyl ether, and the like.

In an additional embodiment, base additives may be added to the photoresist composition. The purpose of the base additive is to scavenge protons present in the photoresist prior to being irradiated by the actinic radiation. The base prevents attack and cleavage of the acid labile groups by the undesirable acids, thereby increasing the performance and stability of the resist. The percentage of base in the composition should be significantly lower than the photoacid generator because it would not be desirable for the base to interfere with the cleavage of the acid labile groups after the photoresist composition is irradiated. The preferred range of the base compounds, when present, is about 3% to 50% by weight of the photoacid generator compound. Examples of useful bases include alkyl amines, cyclic amine, or salts of hydroxide ions. Suitable examples of base additives are 2-methylimidazole, triisopropylamine, 4-dimethylaminopryidine, 4,4′-diaminodiphenyl ether, 2,4,5-triphenylimidazole, tetrabutyl ammonium hydroxide and 1,5-diazobicyclo[4.3.0]non-5-ene.

Dyes may be added to the photoresist to increase the absorption of the composition to the actinic radiation wavelength. The dye must not poison the composition and must be capable of withstanding the process conditions including any thermal treatments. Examples of suitable dyes are fluorenone derivatives, anthracene derivatives or pyrene derivatives. Other specific dyes that are suitable for photoresist compositions are described in U.S. Pat. No. 5,593,812, which is incorporated herein by reference.

The photoresist composition is applied uniformly to a substrate by known coating methods. For example, the coatings may be applied by spin-coating, dipping, knife coating, lamination, brushing, spraying, and reverse-roll coating. The coating thickness range generally covers values of about 0.1 to more than 10 μm. After the coating operation, the solvent is generally removed by drying. The drying step is typically a heating step called ‘soft bake’ where the resist and substrate are heated to a temperature of about 50° C. to 150° C. for about a few seconds to a few minutes; preferably for about 5 seconds to 30 minutes depending on the thickness, the heating element and end use of the resist.

The photoresist compositions are suitable for a number of different uses in the electronics industry. For example, it can be used as electroplating resist, plasma etch resist, solder resist, resist for the production of printing plates, resist for chemical milling or resist in the production of integrated circuits. The possible coatings and processing conditions of the coated substrates differ accordingly.

For the production of relief structures, the substrate coated with the photoresist composition is exposed imagewise. The term ‘imagewise’ exposure includes both exposure through a photomask containing a predetermined pattern, exposure by means of a computer controlled laser beam which is moved over the surface of the coated substrate, exposure by means of computer-controlled electron beams, and exposure by means of X-rays or UV rays through a corresponding mask.

Radiation sources, which can be used, are all sources that emit radiation to which the photoacid generator is sensitive. Examples include high pressure mercury lamp, KrF excimer lasers, ArF excimer lasers, electron beams and x-rays sources. The radiation is preferably of about 248 nm or less.

The process described above for the production of relief structures preferably includes, as a further process measure, heating of the coating between exposure and treatment with the developer. With the aid of this heat treatment, known as “post-exposure bake”, virtually complete reaction of the acid labile groups in the polymer resin with the acid generated by the exposure is achieved. The duration and temperature of this post-exposure bake can vary within broad limits and depend essentially on the functionalities of the polymer resin, the type of acid generator and on the concentration of these two components. The exposed resist is typically subjected to temperatures of about 50° C. to 150° C. for a few seconds to a few minutes. The preferred post exposure bake is from about 80° C. to 130° C. for about 5 seconds to 300 seconds.

After imagewise exposure and any heat treatment of the material, the exposed areas of the photoresist are removed by dissolution in a developer. The choice of the particular developer depends on the type of photoresist; in particular on the nature of the polymer resin or the photolysis products generated. The developer can include aqueous solutions of bases to which organic solvents or mixtures thereof may have been added. Particularly preferred developers are aqueous alkaline solutions. These include, for example, aqueous solutions of alkali metal silicates, phosphates, hydroxides and carbonates, but in particular of tetra alkylammonium hydroxides, and more preferably tetramethylammonium hydroxide (TMAH). If desired, relatively small amounts of wetting agents and/or organic solvents can also be added to these solutions.

After the development step, the substrate carrying the resist coating is generally subjected to at least one further treatment step which changes substrate in areas not covered by the photoresist coating. Typically, this can be implantation of a dopant, deposition of another material on the substrate or an etching of the substrate. This is usually followed by the removal of the resist coating from the substrate using a suitable stripping method.

The resist of this invention may be coated over an undercoat to form a bilayer resist. Films of undercoats are typically spun cast from solvents suitable for photoresist applications and baked similar to photoresists. Film thickness of the undercoat will vary depending on the exact application but generally range from about 800 Angstroms to about 10,000 angstroms. Thicknesses of from about 1500 Angstroms to about 5000 Angstroms are preferred.

Suitable undercoats have several required characteristics. First, there should be no intermixing between the undercoat and resist. Generally this is achieved by casting a film of undercoat and crosslinking it to reduce casting solvent solubility. The crosslinking may be thermally or photochemically induced. Examples of this photochemical and thermal crosslinking may be found in U.S. Pat. Nos. 6,146,793, 6,054,248, 6,323,287, and 6,165,682 and U.S. application Ser. No. 10/093,079 filed on Mar. 7, 2002, based upon U.S. Provisional Patent Application No. 60/275,528 hereby incorporated by reference. Undercoats also generally are designed to have good substrate plasma etch resistance. Generally, the optical (n,k) parameters of a suitable undercoat are optimized for the exposure wavelength to minimize reflections.

Imaging the photosensitive composition of this invention on the overcoat is substantially the same as on a substrate. After images are formed in the radiation sensitive resist, the substrate will be placed in a plasma-etching environment comprising oxygen so that the undercoat will be removed in the area unprotected by the resist. The silicon in the silicon containing monomer unit forms silicon dioxide when exposed to an oxygen plasma and protects the resist from being etched so that relief structures can be formed in the undercoat layer.

After the oxygen plasma step, the substrate carrying the bilayer relief structure is generally subjected to at least on further treatment step which changes the substrate in areas not covered by the bilayer coating. Typically, this can be implantation of a dopant, deposition of another material on the substrate or an etching of the substrate. This is usually followed by the removal of the resist and its byproducts and the undercoat.

The present invention is illustrated by, but not limited to, the following examples.

### EXAMPLE 1

### Synthesis of Poly(Allyltrimethylsilane-Maleic Anhydride-t-butylacrylate-Methylacrylate-Acrylic Acid) [33/33/25/6/3]

A 250-mL round bottom flask was oven dried at 120° C. for 3 hours prior to use. t-Butylacrylate, allyl trimethylsilane, methyl acrylate, and Vazo-67 were removed from cold storage and allowed to warm completely to room temperature. The flask was removed from the oven, cooled under a jet of nitrogen, and equipped with ma gnetic stirring, reflux condenser fitted with N2-inlet adapter, and septum inlet adapter. Allyl-trimethylsilane (40.00 g, 350 mmol), maleic anhydride (34.33 g, 350 mmol), t-butylacrylate (33.99 g, 265.2 mmol), methyl acrylate (5.48 g, 63.7 mmol), acrylic acid (2.29 g, 31.8 mmol) and anhydrous, inhibitor-free tetrahydrofuran (77.8 g, 1.08 mol) were charged to the flask under a positive flow of nitrogen. The flask was then heated to 67° C., and azobis(2-methylbutanenitrile) (0.6731 g, 3.5 mmol) dissolved in 2 mL of tetrahydrofuran were injected into the reactor via the septum inlet adapter. The reaction was allowed to proceed under a nitrogen blanket for 22 hours, and was then cooled to room temperature. The reaction mixture was diluted by addition of 70 mL of dry tetrahydrofuran, and precipitated by dropwise addition to 1400 mL of dry hexanes under a nitrogen pad. The resulting solids were collected by filtration, rinsed, and dried under vacuum. The dry solids were then redissolved in 100 mL of tetrahydrofuran and re-precipitated into 1400 mL of hexanes. The resulting solids were collected by filtration, rinsed, and dried to constant weight under high vacuum at 70° C. to yield 85 g of a white powder. Weight % acid was calculated by reacting the polymer solution with barium perchlorate and then titrating the released perchloric acid with tri(isopropyl)amine. Molar % acid was then calculated using the wt % acid value and monomer unit compositional data from NMR assuming all acid was acrylic acid. The amount of acid found was 2.3 mol % based on acrylic acid.

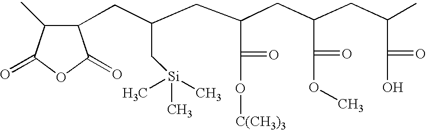

Poly(Allyltrimethylsilane-Maleic Anhydride-t-butylacrylate-Methylacrylate-Acrylic Acid)

### EXAMPLE 2

### Synthesis of Poly(Allyltrimethylsilane-Maleic Anhydride-t-butylacrylate-Methylacrylate-Acrylic Acid) [33/33/25/3/6]

A 250-mL round-bottom flask was oven dried at 120° C. for 3 hours prior to use. t-Butylacrylate, allyl trimethylsilane, methyl acrylate, and Vazo-67 were removed from cold storage and allowed to warm completely to room temperature. The flask was removed from the oven, cooled under a jet of nitrogen, and equipped with magnetic stirring, reflux condenser fitted with an N₂-inlet adapter, and septum inlet adapter. Allyl-trimethylsilane (40.00 g, 350 mmol), maleic anhydride (34.33 g, 350 mmol), t-butylacrylate (33.99 g, 265.2 mmol), methyl acrylate (2.74 g, 31.8 mmol), acrylic acid (4.59 g, 63.7 mmol) and anhydrous, inhibitor-free tetrahydrofuran (77.8 g, 1.08 mol) were charged to the flask under a positive flow of nitrogen. The flask was then heated to 67° C., and azobis(2-methylbutanenitrile) (0.6731 g, 3.5 mmol) dissolved in 2 mL of tetrahydrofuran were injected to the reactor via the septum inlet adapter. The reaction was allowed to proceed under a nitrogen blanket for 22 hours, and was then cooled to room temperature. The reaction mixture was diluted by addition of 70 mL of dry tetrahydrofuran, and precipitated by dropwise addition to 1400 mL of dry hexanes under a nitrogen pad. The resulting solids were collected by filtration, rinsed, and dried under vacuum. The dry solids were then redissolved in 100 mL of tetrahydrofuran and re-precipitated into 1400 mL of hexanes. The resulting solids were collected by filtration, rinsed, and dried to constant weight under high vacuum at 70° C. to yield 88 g of a white powder. The amount of acid was 4.7 mol % based on acrylic acid.

### EXAMPLE 3

### Synthesis of Poly(Allyltrimethylsilane-Maleic Anhydride-t-butylacrylate-Acrylic Acid) [33/33/25/9]

A 250-mL round bottom flask was oven dried at 120° C. for 3 hours prior to use. t-Butylacrylate, allyl trimethylsilane, methyl acrylate, and Vazo-67 were removed from cold storage and allowed to warm completely to room temperature. The flask was removed from the oven, cooled under a jet of nitrogen, and equipped with magnetic stirring, reflux condenser fitted with an N₂-inlet adapter, and septum inlet adapter. Allyl-trimethylsilane (40.00 g, 350 mmol), maleic anhydride (34.33 g, 350 mmol), t-butylacrylate (33.99 g, 265.2 mmol), acrylic acid (6.88 g, 95.5 mmol) and anhydrous, inhibitor-free tetrahydrofuran (77.8 g, 1.08 mol) were charged to the flask under a positive flow of nitrogen. The flask was then heated to 67° C., and azobis(2-methylbutanenitrile) (0.6731 g, 3.5 mmol) dissolved in 2 mL of tetrahydrofuran were injected to the reactor via the septum inlet adapter. The reaction was allowed to proceed under a nitrogen blanket for 22 hours, and was then cooled to room temperature. The reaction mixture was diluted by addition of 70 mL of dry tetrahydrofuran, and precipitated by dropwise addition to 1400 mL of dry hexanes under a nitrogen pad. The resulting solids were collected by filtration, rinsed, and dried under vacuum. The dry solids were then redissolved in 100 mL of tetrahydrofuran and re-precipitated into 1400 mL of hexanes. The resulting solids were collected by filtration, rinsed, and dried to constant weight under high vacuum at 70° C. to yield 82 g of a white powder. The amount of acid was 8.7 mol % based on acrylic acid.

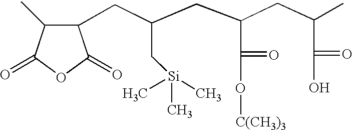

Poly(Allyltrimethylsilane-Maleic Anhydride-t-butylacrylate-Acrylic Acid)

### EXAMPLE 4

### Synthesis of Poly(Allyltrimethylsilane-Maleic Anhydride-t-butylacrylate-Acrylic Acid) [33/33/28/6]

A 250-mL round bottom flask was oven dried at 120° C. for 3 hours prior to use. t-Butylacrylate, allyl trimethylsilane, methyl acrylate, and Vazo-67 were removed from cold storage and allowed to warm completely to room temperature. The flask was removed from the oven, cooled under a jet of nitrogen, and equipped with magnetic stirring, reflux condenser fitted with an N₂-inlet adapter, and septum inlet adapter. Allyl-trimethylsilane (40.00 g, 350 mmol), maleic anhydride (34.33 g, 350 mmol), t-butylacrylate (38.07 g, 297 mmol), acrylic acid (4.59 g, 63.7 mmol) and anhydrous, inhibitor-free tetrahydrofuran (69 g, 951 mmol) were charged to the flask under a positive flow of nitrogen. The flask was then heated to 67° C., and azobis(2-methylbutanenitrile) (0.6731 g, 3.5 mmol) dissolved in 2 mL of tetrahydrofuran were injected to the reactor via the septum inlet adapter. The reaction was allowed to proceed under a nitrogen blanket for 22 hours, and was then cooled to room temperature. The reaction mixture was diluted by addition of 70 mL of dry tetrahydrofuran, and precipitated by dropwise addition to 1400 mL of dry hexanes under a nitrogen pad. The resulting solids were collected by filtration, rinsed, and dried under vacuum. The dry solids were then redissolved in 100 mL of tetrahydrofuran and re-precipitated into 1400 mL of hexanes. The resulting solids were collected by filtration, rinsed, and dried to constant weight under high vacuum at 70° C. to yield a white powder. The amount of acid was 5.5 mol % based on acrylic acid.

### EXAMPLE 5 (COMPARATIVE EXAMPLE)

### Synthesis of Poly(Allyltrimethylsilane-Maleic Anhydride-t-butylacrylate-Methylacrylate) [33/33/25/9]

A 250-mL round bottom flask was oven dried at 120° C. for 3 hours prior to use. t-Butylacrylate, allyl trimethylsilane, methyl acrylate, and Vazo-67 were removed from cold storage and allowed to warm completely to room temperature. The flask was removed from the oven, cooled under a jet of nitrogen, and equipped with magnetic stirring, reflux condenser fitted with an N₂-inlet adapter, and septum inlet adapter. Allyl-trimethylsilane (25.00 g, 218.8 mmol), maleic anhydride (21.46 g, 218.8 mmol), t-butylacrylate (21.24 g, 165.8 mmol), methyl acrylate (5.28 g, 59.3 mmol), and anhydrous, inhibitor-free tetrahydrofuran (64.01 g, 887 mmol) were charged to the flask under a positive flow of nitrogen. The flask was then heated to 67° C., and azobis(2-methylbutanenitrile) (0.3594 g, 2.2 mmol) dissolved in 2 mL of tetrahydrofuran were injected to the reactor via the septum inlet adapter. The reaction was allowed to proceed under a nitrogen blanket for 22 hours, and was then cooled to room temperature. The reaction mixture was diluted by addition of 50 mL of dry tetrahydrofuran, and precipitated by dropwise addition to 1400 mL of dry hexanes under a nitrogen pad. The resulting solids were collected by filtration, rinsed, and dried under vacuum. The dry solids were then redissolved in 50 mL of tetrahydrofuran and re-precipitated into 1400 mL of hexanes. The resulting solids were collected by filtration, rinsed, and dried to constant weight under high vacuum at 70° C. to yield 41 g of a white powder (85% conversion). The amount of acid was below the detection limit of <0.3 mol %.

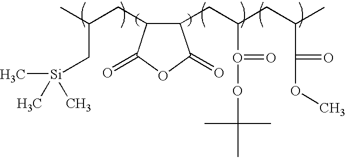

Poly(Allyltrimethylsilane-Maleic Anhydride-t-butylacrylate-Methylacrylate)

The advantageous properties of the binder resins of this invention are demonstrated in the following test results.

In a first test, solutions were made by mixing 8.1695 parts by weight of polymer from the Examples with 0.7839 parts by weight of a photoacid generator of the structure shown as PAG-1, 0.0466 parts by weight of a base of the structure shown as B-1, and 91 parts by weight of propylene glycol monomethyl ether acetate, and then filtered through 0.2 μm Teflon filters.

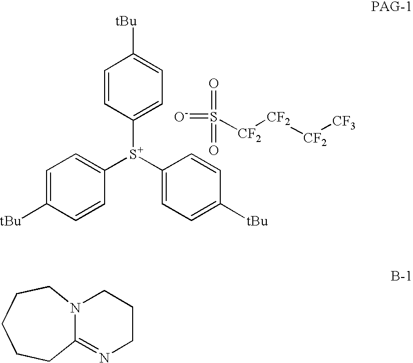

The solutions were then spin coated onto silicon wafers which were coated with an underlayer, one of the thermally cured undercoats described in co-pending U.S. Provisional Patent Application, Serial No. 60/275,528, filed on Mar. 13, 2001, now U.S. regular application Ser. No. 10/093,079, filed Mar. 7, 20092, which are incorporated herein by reference. The wafer is coated to a thickness of 5000 Å and baked at 205° C. for 70 seconds. The photoresists were coated, and baked at 135° C. for 90 seconds to achieve a final film thickness of 2350 Å. The wafers were then exposed on a Canon EX6 (KrF, 248 nm) with numerical aperture of 0.65 annular illumination (partial coherence 0.8 outer, 0.5 inner). The wafers were post-expose baked at 125° C. for 90 seconds, and developed in a commercially available 0.262 N tetramethylammonium hydroxide developer solution (OPD-262, available from Arch Chemical Company). A measurement of contrast was made by first exposing a wafer with a number of open-frame exposures, that is, without a patterned reticle, increasing the energy dose by 1 mJ increments. The wafer was then post-exposure baked and developed, and the film thickness remaining in each exposure was measured. These film thicknesses were then normalized to the initial thickness, and plotted. The contrast is defined as the slope of the line connecting the last full-thickness dose energy to the first completely developed (i.e., 0 thickness) dose energy. In a second measurement, a wafer was exposed imagewise, printing an array of 160 nm contact holes in the film. The resulting fine patterns were then visualized on a scanning electron microscope, and the depth of focus of the contact holes were measured. Table 1 below shows the results of this screening.

TABLE 1
Lithographic results of the first test

| # | Polymer | Contrast | DOF | Image Quality |
|---|---|---|---|---|
| L1-1 | Example 5 | 16.4 | 0.1 nm | Cusp |
| L1-2 | Example 1 | 9.9 | 0.7 nm | Flattops |
| L1-3 | Example 2 | 6.5 | 0.8 nm | Rounded tops |

In a second test, the utility of free acid incorporation is clearly demonstrated. Comparison of L1-1 (no free acid) to L1-2 and L1-3 shows a substantial improvement in the depth of focus of the fine features. However, inspections of L1-3 shows that in the case of the higher amount of acid, contrast suffers to the point where profile quality degrades. Thus, there is unexpectedly a definite, practical upper limit to the amount of free acid which the polymer can contain.

In a second test, solutions were made by mixing 8.1695 parts by weight of polymer from the Examples with 0.7839 parts by weight of a photoacid generator of the structure shown as PAG-1, 0.0466 parts by weight of a base of the structure shown as B-1, and 91 parts by weight of propylene glycol monomethyl ether acetate, and then filtered through 0.2 μm Teflon filters.

The solutions were then spin coated onto silicon wafers which were coated with an underlayer, one of the thermally cured undercoats described above in U.S. Provisional Patent Application, Serial No. 60/275,528, which is coated to a thickness of 5000 Å and baked at 205° C. for 70 seconds. The photoresists were coated, and baked at 135° C. for 90 seconds to achieve a final film thickness of 2350 Å. The wafers were then exposed on a Canon EX6 (KrF, 248 nm) with numerical aperture of 0.65 annular illumination (partial coherence 0.8 outer, 0.5 inner). The wafers were post-expose baked at 125° C. for 90 seconds, and developed in a commercially available 0.262 N tetramethylammonium hydroxide developer solution (OPD-262, available from Arch Chemical Company). A measurement of contrast was made by first exposing a wafer with a number of open-frame exposures, that is, without a patterned reticle, increasing the energy dose by 1 mJ increments. The wafer was then post-exposure baked and developed, and the film thickness remaining in each exposure was measured. These film thicknesses were then normalized to the initial thickness, and plotted. The contrast is defined as the slope of the line connecting the last full-thickness dose energy to the first completely developed (i.e., 0 thickness) dose energy. In a second measurement, a wafer was exposed imagewise, printing an array of 160 nm contact holes in the film. The resulting fine patterns were then visualized on a scanning electron microscope, and the depth of focus of the contact holes were measured. Table 2 below shows the results of this screening.

TABLE 2
Lithographic results of the second test

| | | Mol % | | |
|---|---|---|---|---|
| | | Free | DOF | |
| # | Polymer | Acid | nm | Contrast |
| L2-1 | Example 5 | 0 | 0.1 | 15 |
| L2-2 | 66.67% Example 5 + | 1.83 | 1.0 | 10.9 |
| | 33.33% Example 3 | | | |
| L2-3 | 75% Example 5 + | 1.375 | 0.6 | 12 |
| | 25% Example 3 | | | |
| L2-4 | 83.33% Example 5 + | 0.917 | 0.5 | 12.7 |
| | 16.67% Example 3 | | | |
| L2-5 | 91.66% Example 5 + | 0.459 | 0.5 | 15 |
| | 8.34% Example 3 | | | |

With the foregoing description of the invention, those skilled in the art will appreciate that modifications may be made to the invention without departing from the spirit thereof. Therefore, it is not intended that the scope of the invention be limited to the specific embodiments illustrated and described.

We claim:

1. A binder resin for a radiation-sensitive photoresist composition, the binder resin comprising a polymer having from about 0.1 to about 3 mol % of free acid in the polymer and said polymer having the following monomeric units:
(a) a monomeric unit of a polymerizable carboxylic anhydride;
(b) a monomeric unit of a polymerizable alkenyl silane providing a total silicon content of the polymer of from about 4 to about 15% by weight; and
(c) a monomeric unit of a polymerizable monomer containing an acid labile group, such monomeric unit yielding a base-soluble group on reaction with acid;
with the free acid content of the polymer having been provided by hydrolysis of sufficient of the carboxylic andydride monomeric unit or by the presence in the polymer of
(d) a monomeric unit of a polymerizable monomer containing a free acid group.

2. A binder resin according to claim 1 wherein the free acid content of the polymer is provided by hydrolyzing sufficient carboxylic anhydride monomeric unit.

3. A binder resin according to claim 1 wherein the free acid content of the polymer is provided by the presence in the polymer of momomeric unit (d).

4. A binder resin according to claim 1 wherein the free acid content of the polymer is from about 1.5 to about 2.5 mol %.

5. A binder resin according to claim 3 wherein monomeric unit (a) comprises from about 15 to about 50 mol % of the polymer; monomeric unit (b) comprises from about 15 to about 50 mol % of the polymer; monomeric unit (c) comprises from about 10 to about 40 mol % of the polymer; and monomeric unit (d) comprises from about 0.1 to about 3 mol % of the polymer.

6. A binder resin according to claim 5 wherein the momomeric unit of a polymerizable carboxylic anhydride is a monomeric unit selected from the group consisting of maleic anhydride and itaconic anhydride units; the monomeric unit of polymerizable alkenyl silane is a monomeric unit selected from the group consisting of allyl trimethyl silane and vinyl trimethyl silane units; the monomeric unit of a polymerizable monomer containing an acid labile group contains an acid labile group selected from the group consisting of t-buyl acrylate or methacrylate, t-amyl acrylate or methacrylate, and tetrahydropyranyl acrylate or methacrylate groups; and the monomeric unit of a polymerizable monomer containing a free acid group is a monomeric unit selected from the group consisting of acrylic or methacrylic acid, vinyl acetic acid, maleic acid and substituted maleic acid units.

7. A resin binder according to claim 5 wherein the free acid content of the polymer is from about 1.5 to about 2.5 mol %.

8. A binder resin according to claim 5 wherein the polymer additionally comprises a monomeric unit of a polymerizable monomer with a polymerizable C═C bond.

9. A binder resin according to claim 8 wherein the additional monomeric unit of the polymerizable monomer with a polymerizable C═C bond is a monomeric unit selected from the group consisting of alkyl acrylate, vinyl acetate, styrene, and hydroxystyrene units.

10. A binder resin according to claim 6 comprising monomeric units of maleic anhydride, allyl trimethyl silane, t-butyl acrylate and acrylic acid.

11. A binder resin according to claim 8 comprising monomeric units of maleic anhydride, allyl trimethyl silane, t-butyl acrylate, methylacrylate and acrylic acid.

12. A binder resin according to claim 2 wherein wherein the momomeric unit of a polymerizable carboxylic anhydride is a monomeric unit selected from the group consisting of maleic anhydride and itaconic anhydride units; the monomeric unit of polymerizable alkenyl silane is a monomeric unit selected from the group consisting of allyl trimethyl silane and vinyl trimethyl silane units; and the monomeric unit of a polymerizable monomer containing an acid labile group contains an acid labile group selected from the group consisting of t-buyl acrylate or methacrylate, t-amyl acrylate or methacrylate, and tetrahydropyranyl acrylate or methacrylate groups.

13. A radiation sensitive composition comprising:
(1) a binder resin comprising a polymer having from about 0.1 to about 3 mol % of free acid in the polymer and said polymer having the following monomeric units:
(a) a monomeric unit of a polymerizable carboxylic anhydride;
(b) a monomeric unit of a polymerizable alkenyl silane providing a total silicon content of the polymer of from about 4 to about 15% by weight; and
(c) a monomeric unit of a polymerizable monomer containing an acid labile group, such monomeric unit yielding a base-soluble group on reaction with acid;
with the free acid content of the polymer having been provided by hydrolysis of sufficient of the carboxylic andydride monomeric unit or by the presence in the polymer of
(d) a monomeric unit of a polymerizable monomer containing a free acid group;
(2) a photoacid generator compound; and
(3) a solvent capable of dissolving components (1) and (2).

14. A radiation sensitive composition according to claim 13 wherein the free acid content of the polymer is provided by having hydrolyzed sufficient carboxylic anhydride monomeric unit.

15. A radiation sensitive composition according to claim 13 wherein the free acid content of the polymer is provided by the presence in the polymer of momomeric unit (d).

16. A radiation sensitive composition according to claim 13 wherein the free acid content of the polymer is from about 1.5 to about 2.5 mol %.

17. A radiation sensitive composition according to claim 15 wherein monomeric unit (a) comprises from about 15 to about 50 mol % of the polymer; monomeric unit (b) comprises from about 15 to about 50 mol % of the polymer; monomeric unit (c) comprises from about 10 to about 40 mol % of the polymer; and monomeric unit (d) comprises from about 0.1 to about 3 mol % of the polymer.

18. A radiation sensitive composition according to claim 17 wherein the momomeric unit of a polymerizable carboxylic anhydride is a monomeric unit selected from the group consisting of maleic anhydride and itaconic anhydride units; the monomeric unit of polymerizable alkenyl silane is a monomeric unit selected from the group consisting of allyl trimethyl silane and vinyl trimethyl silane units; the monomeric unit of a polymerizable monomer containing an acid labile group contains an acid labile group selected from the group consisting of t-buyl acrylate or methacrylate, t-amyl acrylate or methacrylate, and tetrahydropyranyl acrylate or methacrylate groups; and the monomeric unit of a polymerizable monomer containing a free acid group is a monomeric unit selected from the group consisting of acrylic or methacrylic acid, vinyl acetic acid, maleic acid and substituted maleic acid units.

19. A radiation sensitive composition according to claim 17 wherein the free acid content of the polymer is from about 1.5 to about 2.5 mol %.

20. A radiation sensitive composition according to claim 17 wherein the polymer of the binder resin additionally comprises a monomeric unit of a polymerizable monomer with a polymerizable C═C bond.

21. A radiation sensitive composition according to claim 20 wherein the additional monomeric unit of the polymerizable monomer with a polymerizable C═C bond is a monomeric unit selected from the group consisting of alkyl acrylate, vinyl acetate, styrene, and hydroxystyrene units.

22. A radiation sensitive composition according to claim 18 comprising monomeric units of maleic anhydride, allyl trimethyl silane, t-butyl acrylate and acrylic acid.

23. A radiation sensitive composition according to claim 20 comprising monomeric units of maleic anhydride, allyl trimethyl silane, t-butyl acrylate, methylacrylate and acrylic acid.

24. A radiation sensitive composition according to claim 14 wherein the momomeric unit of a polymerizable carboxylic anhydride is a monomeric unit selected from the group consisting of maleic anhydride and itaconic anhydride units; the monomeric unit of polymerizable alkenyl silane is a monomeric unit selected from the group consisting of allyl trimethyl silane and vinyl trimethyl silane units; and the monomeric unit of a polymerizable monomer containing an acid labile group contains an acid labile group selected from the group consisting of t-buyl acrylate or methacrylate, t-amyl acrylate or methacrylate, and tetrahydropyranyl acrylate or methacrylate groups.

25. A radiation sensitive composition according to claim 13 wherein the photoacid generator compound is a compound selected from the group consisting of onium salts, oxime sulfonates, nitobenzyl esters of carboxylic or sulfonic acids and alkyl halides or gem-halides that release halo acids.

26. A radiation sensitive composition according to claim 25 wherein the composition additionally comprises one or more additional components selected from the group consisting of photobase generators, basic compounds for limiting diffusion lengths of photogenerated acids, crosslinking agents, dissolution inhibitors, adhesion promoters and surfactants.

27. A radiation sensitive composition according to claim 26 wherein the photoacid generator is selected from the group consisting of iodonium and sulfonium salts; and a basic compound is present in the composition and is selected from the group consisting of 2-methylimidazole, triisopropylamine, 4-dimethylaminopryidine, 4,4′-diaminodiphenyl ether, 2,4,5-triphenylimidazole, tertiarybutyl ammonium hydroxide, and 1,5-diazobicyclo[4.3.0]non-5-ene.

28. A method for producing a resist image on a substrate comprising:
a) coating the substrate with a radiation sensitive composition of claim 11;
b) imagewise exposing the photoresist composition on the substrate to actinic radiation; and
c) developing the photoresist composition with a developer to produce a resist image.

29. The method according to claim 28 wherein the actinic radiation is of a wavelength of about 248 nm or less.

30. The method according to claim 29 wherein the developer is tetramethylammonium hydroxide.

31. A method for producing a resist image on a substrate comprising:
d) coating the substrate with a radiation sensitive composition of claim 19;
e) imagewise exposing the photoresist composition on the substrate to actinic radiation; and
f) developing the photoresist composition with a developer to produce a resist image.
